(19) United States
(12) Patent Application Publication
(10) Pub. No.: US 2026/0068380 A1
(43) Pub. Date: Mar. 5, 2026

(54) DISPLAY PANEL AND DISPLAY APPARATUS

(71) Applicant: Wuhan Tianma Microelectronics Co., Ltd., Wuhan (CN)

(72) Inventor: Shaoya QIU, Wuhun (CN)

(73) Assignee: Wuhan Tianma Microelectronics Co., Ltd., Wuhan (CN)

(21) Appl. No.: 19/036,015

(22) Filed: Jan. 24, 2025

(30) Foreign Application Priority Data
Aug. 29, 2024 (CN) 202411205234.X

(51) Int. Cl. H10H 29/34; H10H 29/49; H10H 29/855

(52) U.S. Cl. CPC H10H 29/345; H10H 29/49; H10H 29/855; H10H 29/8552

(57) ABSTRACT

The present application discloses a display panel and a display apparatus. The display panel includes a plurality of pixel units arranged in an array in a first direction and a second direction intersecting each other, and the pixel unit comprises a first pixel and a second pixel; a display mode of the display panel comprises a first mode and a second mode; in the first mode, the first pixel and the second pixel both emit light, and a minimum spacing distance in the first direction between sub-pixels in a light-emitting state and having a same light-emission color is a1; in the second mode, the first pixel does not emit light, the second pixel emits light, and a minimum spacing distance in the first direction between sub-pixels in the light-emitting state and having the same light-emission color is b1, and a1=b1.

### CROSS REFERENCE TO RELATED APPLICATION

The present application claims priority to Chinese Patent Application No. 202411205234.X filed on Aug. 29, 2024, which is incorporated herein by reference in its entirety.

### TECHNICAL FIELD

The present application relates to the field of display, and in particular to a display panel and a display apparatus.

### BACKGROUND

As the application of display panels in mobile phones, watches and other devices continues to mature, the application areas of display panels are also expanding. For example, in recent years, the application of display panels in cars and laptops has gradually increased. During the use process, consumers' demands are also constantly increasing, such as the requirements for the anti-peeping performance of display panels.

### SUMMARY

In a first aspect, an embodiment of the present application provides a display panel, including a plurality of pixel units arranged in an array in a first direction and a second direction intersecting each other, the pixel unit comprises a first pixel and a second pixel, and a light output viewing angle of the first pixel is greater than a light output viewing angle of the second pixel; a display mode of the display panel comprises a first mode and a second mode; in the first mode, the first pixel and the second pixel both emit light, a minimum spacing distance in the first direction between sub-pixels in a light-emitting state in the i-th pixel unit and the j-th pixel unit and having a same light-emission color is a1, and the i-th pixel unit and the j-th pixel unit are adjacent; in the second mode, the first pixel does not emit light, the second pixel emits light, and a minimum spacing distance in the first direction between sub-pixels in a light-emitting state in the i-th pixel unit and the j-th pixel unit and having the same light-emission color is b1, and a1=b1; wherein at least one of the pixel units comprises a plurality of sub-pixel groups with different light-emission colors, and the sub-pixels in the sub-pixel groups are spaced apart by partition walls, and the first direction intersects with an extending direction of the partition walls.

Based on the same inventive concept, in a second aspect, an embodiment of the present application provides a display apparatus, including a display panel as described in the embodiment of the first aspect.

The above description is only an overview of the technical solution of the present application. In order to more clearly understand the technical means of the present application, it can be implemented according to the content of the specification, and in order to make the above and other purposes, features and advantages of the present application more obvious and easy to understand, the specific implementation methods of the present application are specifically cited below.

### BRIEF DESCRIPTION OF THE DRAWINGS

By reading the following detailed description of the non-limiting embodiments with reference to the drawings, other features, purposes and advantages of the present application will become more apparent, wherein the same or similar reference numerals represent the same or similar features, and the drawings are not drawn according to the actual scale.

FIG. 1 shows a schematic structural diagram of a pixel arrangement of a display panel in the related art;

FIG. 2 shows a schematic structural diagram of a pixel arrangement of a display panel provided in an embodiment of the present application;

FIG. 3 shows display schematic diagrams of the display panel of the structure shown in FIG. 2 in two modes respectively;

FIG. 4 shows a schematic structural diagram of another pixel arrangement of the display panel provided in an embodiment of the present application;

FIG. 5 shows display schematic diagrams of the display panel of the structure shown in FIG. 4 in two modes respectively;

FIG. 6 shows schematic structural diagram of another pixel arrangement of the display panel provided in an embodiment of the present application;

FIG. 7 shows display schematic diagrams of the display panel of the structure shown in FIG. 6 in two modes respectively;

FIG. 8 shows another schematic diagram of the pixel arrangement structure of the display panel provided in an embodiment of the present application;

FIG. 9 shows display schematic diagrams of the display panel of the structure shown in FIG. 8 in two modes respectively;

FIG. 10 shows a schematic structural cross-sectional view along the A-A′ direction in FIG. 2;

FIG. 11 shows a schematic structural cross-sectional view along the B-B′ direction in FIG. 4;

FIG. 12 shows a schematic structural cross-sectional view along the C-C′ direction in FIG. 6;

FIG. 13 shows a schematic structural diagram of a top view of a local area of the display panel provided in an embodiment of the present application;

FIG. 14 shows a schematic structural diagram of a circuit of a pixel driving circuit in the display panel provided in an embodiment of the present application;

FIG. 15 shows a time sequence diagram of FIG. 14;

FIG. 16 shows another time sequence diagram of FIG. 14;

FIG. 17 shows a schematic diagram of a connection between a circuit and a pixel in the display panel provided in an embodiment of the present application; and

FIG. 18 shows a schematic structural diagram of a display apparatus provided in an embodiment of the present application.

### REFERENCE NUMERALS

100, display panel;
10, pixel unit; 10i, i-th pixel unit; 10j, j-th pixel unit;
11, first pixel; 111, first sub-pixel;
12, second pixel; 121, second sub-pixel;
13, sub-pixel group; 131, first sub-pixel group; 131, second sub-pixel group; 133, third sub-pixel group;
20, partition wall;
PDL, pixel definition layer;
31, first light-guiding structure; 311, first lens layer; 312, first filling layer; f1, first arc surface; 301, first light-guiding unit;
32, second light-guiding structure; 321, second lens layer; 322, second filling layer; f2, second arc surface; 302, second light-guiding unit;
41, first light-shielding structure; c1, first side surface; c2, second side surface;
42, second light-shielding structure;
50, pixel driving circuit;
60, gating module;
71, first connecting line; 72, second connecting line;
1000, display apparatus.

### DETAILED DESCRIPTION

The features and exemplary embodiments of various aspects of the present application will be described in detail below. In order to make the purpose, technical solutions and advantages of the present application clearer, the present application will be further described in detail below in conjunction with the drawings and specific embodiments. It should be understood that the specific embodiments described herein are only configured to explain the present application and are not configured to limit the present application. For those skilled in the art, the present application can be implemented without some of these specific details. The following description of the embodiments is only to provide a better understanding of the present application by showing examples of the present application.

It should be noted that in the present application, relational terms such as first and second are only used to distinguish one entity or operation from another entity or operation, and do not necessarily require or imply any such actual relationship or order between these entities or operations. Moreover, the terms “include”, “comprise” or any other variant thereof are intended to cover non-exclusive inclusion, so that a process, method, article or device including a series of elements includes not only those elements, but also other elements not explicitly listed, or also includes elements inherent to such a process, method, article or device. In the absence of further restrictions, the elements defined by the sentence “include . . . ” do not exclude the existence of other identical elements in the process, method, article or device including the elements.

It should be understood that when describing the structure of a component, when a layer or an area is referred to as being “on” or “above” another layer or another area, it may refer to being directly above another layer or another area, or containing other layers or areas between it and another layer or another area. Moreover, if the component is turned over, the layer or an area will be “under” or “below” another layer or another area.

It should be understood that the term “and/or” used in the present application is only a description of the association relationship of the associated objects, indicating that there may be three relationships, for example, A and/or B, which may represent: A exists alone, A and B exist at the same time, and B exists alone. In addition, the character “/” in the present application generally indicates that the front and back associated objects are in an “or” relationship.

In the description of the embodiments of the present application, unless otherwise clearly specified and limited, the technical terms “installation”, “link”, “connection”, “fixation” and the like should be understood in a broad sense, for example, may be a fixed connection, a detachable connection, or an integral body; may also be a mechanical connection or an electrical connection; may be directly connected or indirectly connected through an intermediate medium, may be the internal connection of two elements or the interaction relationship between two elements. For those skilled in the art, the specific meanings of the above terms in the embodiments of the present application can be understood according to the specific circumstances.

It is obvious to those skilled in the art that various modifications and changes can be made in the present application without departing from the spirit or scope of the present application. Therefore, the present application is intended to cover modifications and changes of the present application that fall within the scope of the corresponding claims (technical solutions claimed for protection) and their equivalents. It should be noted that the implementation methods provided in the embodiments of the present application can be combined with one another without contradiction.

Before explaining the technical solutions provided in the embodiments of the present application, in order to facilitate the understanding of the embodiments of the present application, the present application first specifically explains the problems existing in the relevant technology:

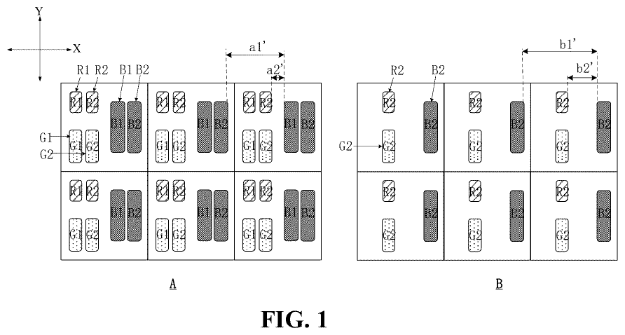

As described in the background art, a display panel in the related art is prone to poor display when switched to the anti-peeping mode. The inventors found that this is because the spacing distance between the displayed sub-pixels may increase when the display panel is switched to the anti-peeping display mode, which is prone to generate grid patterns, thereby causing the display panel to be prone to poor display when switched to the anti-peeping mode. Specifically, referring to FIG. 1, image A in FIG. 1 indicates the sub-pixels that emit light in a normal display mode, sub-pixels R1, R2, G1, G2, B1, and B2 in image A all emit light, and image B indicates the sub-pixels that emit light in the anti-peeping display mode, sub-pixels R2, G2, and B2 in the image B emit light, sub-pixels R1, G1, and B1 do not emit light (the sub-pixels that do not emit light in the image B are hidden). In the normal display mode, a minimum spacing distance in the first direction X between blue sub-pixels in the light-emitting state in adjacent two of the pixel units and having a same light-emission color is a1′, a minimum spacing distance in the first direction X between the red sub-pixel and the blue sub-pixel in the light-emitting state in a same one of the pixel units and having different light-emission colors is a2′. In the anti-peeping display mode, a minimum spacing distance in the first direction X between blue sub-pixels in the light-emitting state in the two pixel units and having a same light-emission color is b1′, a minimum spacing distance in the direction X between the red sub-pixel and the blue sub-pixel in the light-emitting state in a same one of the pixel units and having a same light-emission color is b2′. It can be seen that b1′>a1′, b2′>a2′. It can be seen that in the display panel in the related art, in the anti-peeping display mode, a spacing distance between adjacent sub-pixels in the light-emitting state becomes larger.

In order to solve at least one of the above technical problems, embodiments of the present application provide a display panel and a display apparatus, the embodiments of the display panel and the display apparatus are described below in conjunction with the drawings.

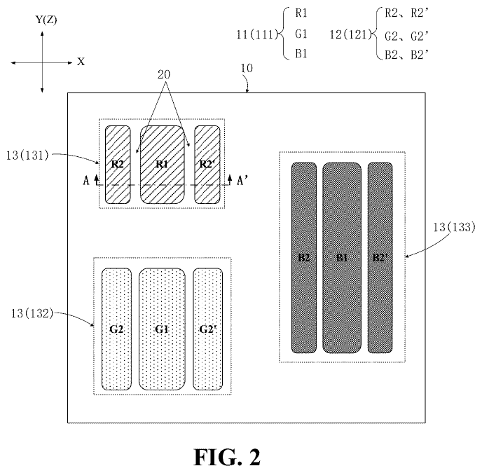

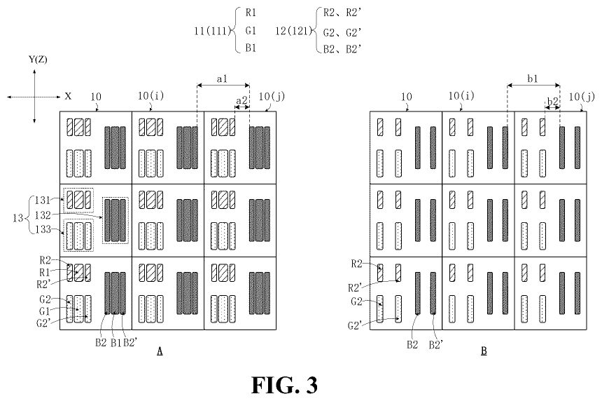

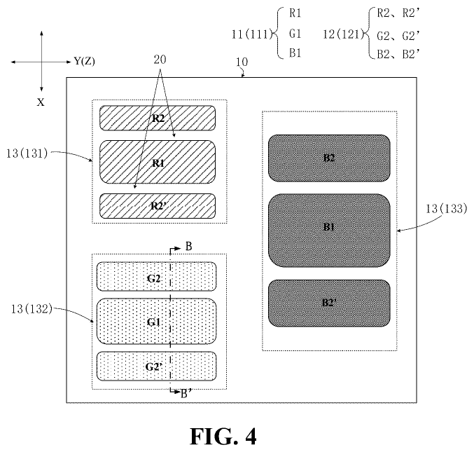

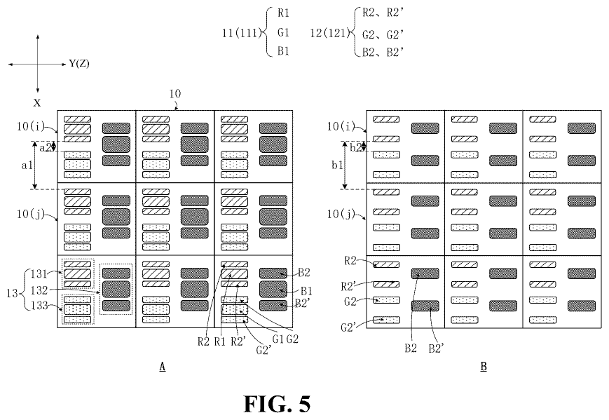

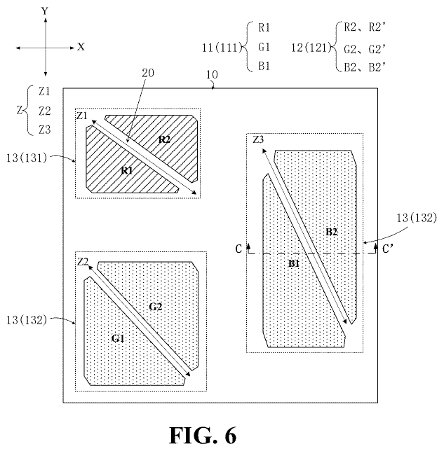

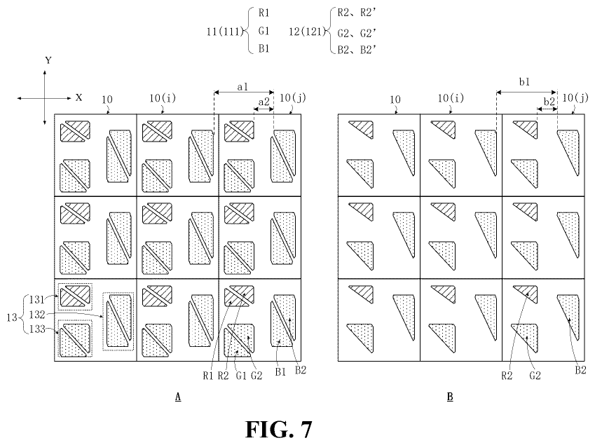

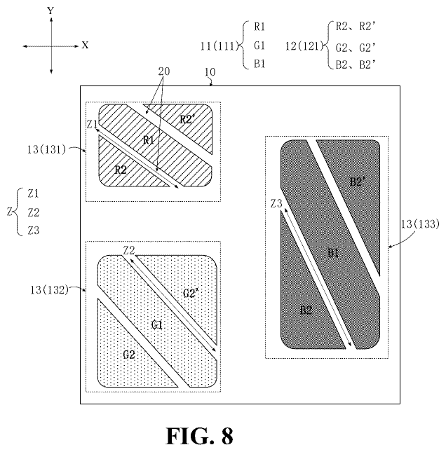

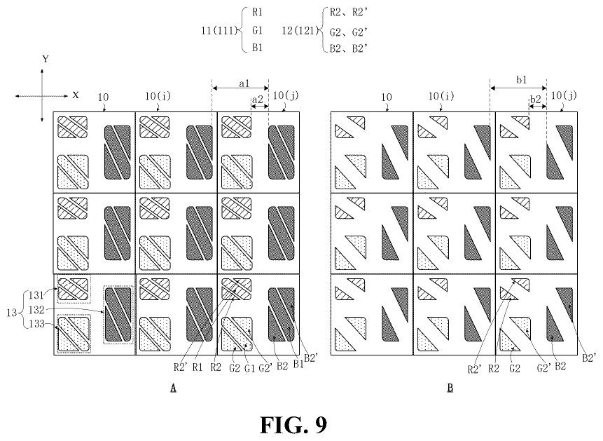

FIG. 2, FIG. 4, FIG. 6, and FIG. 8 show schematic diagrams of some pixel arrangement structures of a display panel provided in the embodiments of the present application. FIG. 3, FIG. 5, FIG. 7, and FIG. 9 show display schematic diagrams based on the pixel arrangement structures of FIG. 2, FIG. 4, FIG. 6, and FIG. 8 in two modes, respectively. Images A of FIG. 3, FIG. 5, FIG. 7, and FIG. 9 all represent sub-pixels that emit light in a first mode, and images B of FIG. 3, FIG. 5, FIG. 7, and FIG. 9 all represent sub-pixels that emit light in a second mode, and the sub-pixels that do not emit light are hidden in the images B of FIG. 3, FIG. 5, FIG. 7, and FIG. 9. In addition, sub-pixels filled with the same texture pattern in the drawings of the present application represent sub-pixels with the same light-emission color, and sub-pixels filled with different texture patterns represent sub-pixels with different light-emission colors.

As shown in FIG. 3, FIG. 5, FIG. 7, and FIG. 9, the display panel provided in the embodiments of the present application comprises a plurality of pixel units 10, the plurality of pixel units 10 are distributed in an array in the first direction X and the second direction Y intersecting each other. It is noted that FIG. 3, FIG. 5, FIG. 7, FIG. 9 show nine pixel units 10 distributed by 3*3, but it is not intended to limit the number of pixel units, the number of pixel units may be set according to actual needs.

Pixel unit 10 comprises a first pixel 11 and a second pixel 12, wherein a light output viewing angle of the first pixel 11 is larger than that of the second pixel 12. The first pixel 11 is a pixel with a wide viewing angle, the second pixel 12 is a pixel with a narrow viewing angle.

Exemplarily, a light-guiding structure may be disposed on one side of a pixel where light is output, for example, the light-guiding structure corresponding to the first pixel has a divergent or diffusing effect on the light rays emitted from the first pixel, the light-guiding structure corresponding to the second pixel has a converging effect on the light rays emitted from the second pixel, so that a light output viewing angle of the first pixel is larger than that of the second pixel.

Some design methods for the first pixel 11 and the second pixel 12 to achieve different light output viewing angles will be introduced below.

Exemplarily, the first pixel 11 comprises sub-pixels of multiple light-emission colors, the second pixel 12 comprises sub-pixels of multiple light-emission colors. For ease of distinction, sub-pixels included in first pixel 11 are labeled as R1, G1, and B1 in the figures of the present application, sub-pixels included in second pixel 12 are labeled as R2, G2, and B2, Alternatively, in some examples, sub-pixels included in second pixel 12 also comprises sub-pixels labeled as R2′, G2′, and B2′.

The pixel unit 10 comprises multiple sub-pixel groups 13 having different light-emission colors, sub-pixels in the same sub-pixel group 13 are spaced apart by partition walls 20, an extending direction of the partition walls 20 is a third direction Z, and the first direction X intersects with the third direction Z. The intersection of two directions herein includes that the two directions are perpendicular or at a certain angle with respect to each other.

It is noted that, as shown in FIG. 2, different sub-pixel groups 13 are also spaced apart, “a partition wall” herein refers to a partition wall between sub-pixels with the same light-emission color in the same sub-pixel group 13.

For example, the sub-pixel group 13 includes a first sub-pixel group 131, a second sub-pixel group 132, and a third sub-pixel group 133, light-emission colors of the first sub-pixel group 131, the second sub-pixel group 132 and the third sub-pixel group 133 are red, green and blue, respectively. Taking FIG. 2 as an example, the first sub-pixel group 131 includes sub-pixels R1, R2, R2′, the second sub-pixel group 132 includes sub-pixels G1, G2, and G2′, and the third sub-pixel group 133 includes sub-pixels B1, B2, and B2′.

Exemplarily, in FIG. 3, FIG. 7 and FIG. 9, the first direction X is parallel to an extending direction of a scan line of the display panel, the first direction X intersects with the scan line of the display panel in FIG. 5, for example, the first direction X is parallel to a data line of the display panel in FIG. 5, wherein the extending directions of the scan line and the data line intersects, the first direction X is related to an arrangement direction of a plurality of sub-pixels in the sub-pixel group 13. The extending direction of the scan line may be referred to a row direction, the extending direction of the data line may be referred to a column direction.

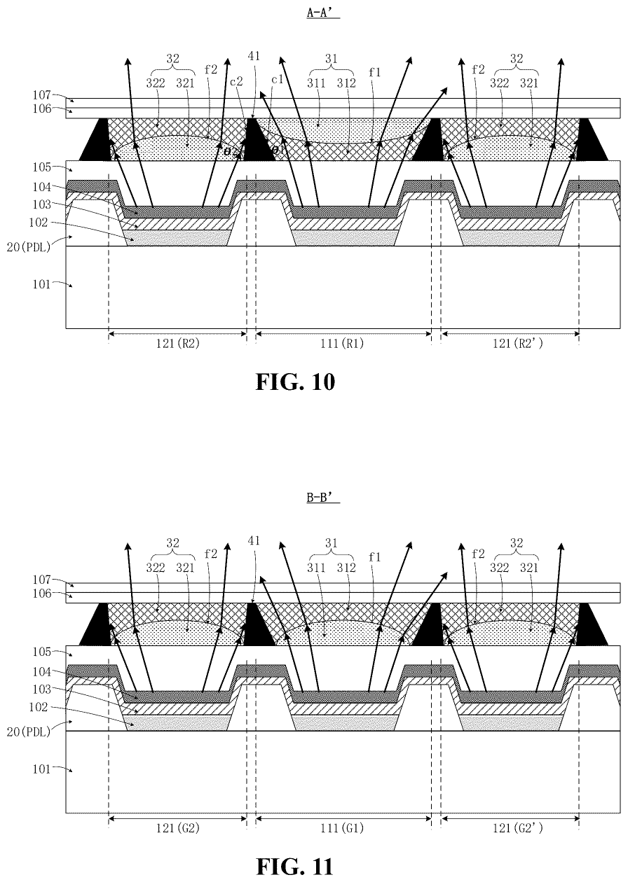

The partition walls 20 are used to space apart different sub-pixels in the same sub-pixel groups. As an example, as shown in FIG. 10, the display panel includes a pixel definition layer PDL, the pixel definition layer includes openings, the light-emitting structures of sub-pixels correspond to the openings of the pixel definition layer PDL, and the partition wall 20 may include the pixel definition layer PDL of the display panel.

The display mode of the display panel includes a first mode and a second mode, display viewing angles of the first mode and the second mode in the display panel are different. In the present application, taking an example that the display viewing angle of the first mode in the display panel is larger than the display viewing angle of the second mode in the display panel. The first mode may be also referred to a normal display module, the second mode may be also referred to an anti-peeping display mode.

As shown in the images A in FIG. 3, FIG. 5, FIG. 7 and FIG. 9, in the first mode, the first pixels 11 and the second pixels 12 all emit light, so that when the first pixels 11 and the second pixels 12 emit light simultaneously, the first pixels 11 and the second pixels 12 can compensate one another to ensure the fineness degree of display quality of the display panel in the first mode.

As shown in images B in FIG. 3, FIG. 5, FIG. 7 and FIG. 9, in the second mode, the first pixels do not emit light (the first pixels that do not emit light are hidden in the images B), and the second pixels 12 all emit light. Since the light output viewing angles of the second pixels 12 are small, only the second pixels 12 emit light, thereby reducing or even eliminating the light rays at a large viewing angel, making the large viewing angle picture invisible, so as to realize the anti-peeping function.

Further, taking an example that the i-th pixel unit 10i and the j-th pixel unit 10j are adjacent in the first direction X, the i-th pixel unit 10i and the j-th pixel unit 10j may be any adjacent of the two pixel units. In the first mode, a minimum spacing distance in the first direction X between sub-pixels in a light-emitting state in the i-th pixel unit 10i and the j-th pixel unit 10j and having a same light-emission color is a1. In the second mode, a minimum spacing distance in the first direction X between sub-pixels in the light-emitting state in the i-th pixel unit 10i and the j-th pixel unit 10j and having a same light-emission color is b1, a1=b1.

It should be noted that a spacing distance a1 and a spacing distance b1 refer to a minimum spacing distance in the first mode between two sub-pixels that are in the light-emitting state and have the same light-emission color and a minimum spacing distance in the second mode between two sub-pixels that are in the light-emitting state and have the same light-emission color respectively. For example, a spacing distance a1 and a spacing distance b1 in FIG. 3 indicate a spacing distance in the first mode between the sub-pixel B2′ in the i-th pixel unit 10i and the sub-pixel B2 in the j-th pixel unit 10j and a spacing distance in the second mode between the sub-pixel B2′ in the i-th pixel unit 10i and the sub-pixel B2 in the j-th pixel unit 10j respectively. As another example, a spacing distance a1 and a spacing distance b1 in FIG. 5 indicate a spacing distance in the first mode between the sub-pixel R2′ in the i-th pixel unit 10i and the sub-pixel R2 in the j-th pixel unit 10j and a spacing distance in the second mode between the sub-pixel R2′ in the i-th pixel unit 10i and the sub-pixel R2 in the j-th pixel unit 10j respectively. As another example, a spacing distance a1 and a spacing distance b1 in FIG. 7 indicate a spacing distance in the first mode between the sub-pixel B2 in the i-th pixel unit 10i and the sub-pixel B2 in the j-th pixel unit 10j and a spacing distance in the second mode between the sub-pixel B2 in the i-th pixel unit 10i and the sub-pixel B2 in the j-th pixel unit 10j respectively. As another example, a spacing distance a1 and a spacing distance b1 in FIG. 9 indicate a spacing distance in the first mode between the sub-pixel B2′ in the i-th pixel unit 10i and the sub-pixel B2 in the j-th pixel unit 10j and a spacing distance in the second mode between the sub-pixel B2′ in the i-th pixel unit 10i and the sub-pixel B2 in the j-th pixel unit 10j respectively.

It should be noted that, taking FIG. 3 as an example, although FIG. 3 only marks the spacing distance in the first direction X between the sub-pixel B2′ in the i-th pixel unit 10i and the sub-pixel B2 in the j-th pixel unit 10j. In the first direction X, the minimum spacing distance in the first mode between the sub-pixel R2′ in the i-th pixel unit 10i and the sub-pixel R2 in the j-th pixel unit 10j and the minimum spacing distance in the second mode between the sub-pixel R2′ in the i-th pixel unit 10i and the sub-pixel R2 in the j-th pixel unit 10j are equal, the minimum spacing distance in the first mode between the sub-pixel G2′ in the i-th pixel unit 10i and the sub-pixel G2 in the j-th pixel unit 10j and the minimum spacing distance in the second mode between the sub-pixel G2′ in the i-th pixel unit 10i and the sub-pixel G2 in the j-th pixel unit 10j are equal. The spacing distances in the first direction between sub-pixels of other colors in FIGS. 5, 7, and 9 are similar, which are not repeated herein.

The display panel provided in the embodiments of the present application includes two display modes, and in the two display modes, the minimum spacing distances in the first direction between sub-pixels in a light-emitting state in adjacent two of the pixel units and having a same light-emission color are equal, so that when the two display modes are switched, the spacing distance in any one of the display modes between the light-emitting sub-pixels having the same color is avoided to increase, thereby ensuring the fineness degree of the display in any one of display modes and avoiding the occurrence of poor display conditions such as grid patterns.

In some embodiments, still referring to FIGS. 3, 5, 7 and 9, in the first mode, the minimum spacing distance in the first direction between sub-pixels in a light-emitting state in a same one of the pixel units 10 and having a first light-emission color and a second light-emission color respectively is a2, and in the second mode, the minimum spacing distance in the first direction between sub-pixels in the light-emitting state in the same one of the pixel units and having the first light-emission color and the second light-emission color respectively is b2, where a2=b2.

It should be noted that the spacing distance a2 and the spacing b2 refer to the minimum spacing distance in the first mode between two sub-pixels in the light-emitting state and having different light-emission colors and the minimum spacing distance in the second mode between two sub-pixels in the light-emitting state and having different light-emission colors respectively. For example, the spacing distance a2 and the spacing distance b2 in FIG. 3 represent the spacing distance in the first mode between the sub-pixel R2′ and the sub-pixel B2 in a same one of the pixel units 10 and the spacing distance in the second mode between the sub-pixel R2′ and the sub-pixel B2 in the same one of the pixel units 10 respectively. For another example, the spacing distance a2 and the spacing distance b2 in FIG. 5 represent the spacing distance in the first mode between the sub-pixel R2′ and the sub-pixel G2 in the same one of the pixel units 10 and the spacing distance in the second mode between the sub-pixel R2′ and the sub-pixel G2 in the same one of the pixel units 10 respectively. For another example, the spacing distance a2 and the spacing distance b2 in FIG. 7 represent the spacing distance in the first mode between the sub-pixel R2 and the sub-pixel B2 in the same one of the pixel units 10 and the spacing distance in the second mode between the sub-pixel R2 and the sub-pixel B2 in the same one of the pixel units 10 respectively. For another example, the spacing distance a2 and the spacing distance b2 in FIG. 9 represent the spacing distance in the first mode between the sub-pixel R2′ and the sub-pixel B2 in the same one of the pixel units 10 and the spacing distance in the second mode between the sub-pixel R2′ and the sub-pixel B2 in the same one of the pixel units 10 respectively.

It should be noted that, although FIG. 3 only marks the spacing distance in the first direction X between the sub-pixel R2′ and the sub-pixel B2 in the same one of the pixel units 10, in the first direction X, the minimum spacing distance in the first mode between the sub-pixel G2′ and the sub-pixel B2 in the same one of the pixel units 10 and the minimum spacing distance in the second mode between the sub-pixel G2′ and the sub-pixel B2 in the same one of the pixel units 10 are equal. The spacing distances in the first direction between sub-pixels in FIGS. 5 to 7 and 9 are similar, which are not be repeated herein.

In the display panel provided by the embodiments of the present application, in the two display modes, the minimum spacing distances in the first direction between sub-pixels in the light-emitting state in the same one of the pixel units and having different light-emission colors are equal, so that when the two display modes are switched, the spacing distance in any one of display modes between the light-emitting sub-pixels having different colors is avoided to increase, thereby further ensuring the fineness degree of the display in any one of display modes, and better avoiding the occurrence of poor display conditions such as grid patterns.

In some examples, as shown in FIGS. 3, 5, 7 and 9, the same sub-pixel group 13 includes n1 first sub-pixels 111 and n2 second sub-pixels 121 with a same light-emission color, a light output viewing angle of the first sub-pixels 111 is greater than a light output viewing angle of the second sub-pixels 121, the first pixel 11 includes the first sub-pixels 111, the second pixel 12 includes the second sub-pixels 121, and n1 and n2 are integers greater than 0.

For example, the first sub-pixels 111 include the sub-pixels R1, G1, and B1 in the drawings, and the second sub-pixels 121 include the sub-pixels R2, G2, and B2 in the drawings, or, in some examples, the second sub-pixels 121 also include the sub-pixels R2′, G2′, and B2′ in the drawings, wherein the sub-pixels with the reference symbol “R” represent red sub-pixels, the sub-pixels with the reference symbol “G” represent green sub-pixels, and the sub-pixels with the reference symbol “B” represent blue sub-pixels. The light output viewing angles of sub-pixels R2, G2, and B2 and sub-pixels R2′, G2′, and B2′ may be the same, or the light output viewing angles of sub-pixels R2, G2, and B2 and sub-pixels R2′, G2′, and B2′ have a variation within the allowable error range.

In a same one of the pixel units 10, the n1 first sub-pixels 111 are arranged in a same rule for the sub-pixel groups 13 each, the n2 second sub-pixels 121 are arranged in a same rule for the sub-pixel groups 13 each, and the overall shapes of different sub-pixel groups 13 are similar.

The arrangement rule includes the arrangement order of sub-pixels. The arrangement order of sub-pixels includes: the arrangement order of multiple sub-pixels in the sub-pixel group 13. For example, the arrangement rule in each sub-pixel group 13 in FIG. 2 is that: 1 first sub-pixel 111 and 2 second sub-pixels 121 are arranged along the first direction X, and the first sub-pixel 111 is located between the 2 second sub-pixels 121.

The overall shape of the sub-pixel group 13 includes: an overall shape formed by an orthographic projection of the sub-pixel group 13 on a plane where the display panel is located. Still taking FIG. 2 as an example, the orthographic projections of the first sub-pixel 111 and the second sub-pixel 121 on the plane where the display panel is located are roughly rectangular, ignoring the intervals between different sub-pixels in the sub-pixel group 13, and the overall shape formed by the orthographic projection of the sub-pixel group 13 on the plane where the display panel is located is roughly rectangular.

In the embodiments of the present application, each sub-pixel group includes first sub-pixels and second sub-pixels, and the sub-pixels of different sub-pixel groups have the same arrangement rules, and the overall shapes of different sub-pixel groups are similar, so that the spacing distances of the light-emitting sub-pixels may not change in the two display modes.

In some embodiments, as shown in FIGS. 3, 5, 7 and 9, the same sub-pixel group 13 includes n1 first sub-pixels 111 and n2 second sub-pixels 121 with a same light-emission color, the light output view angle of first sub-pixel 111 is greater than the light output view angle of second sub-pixel 121, first pixel 11 includes first sub-pixels 111, second pixel 12 includes second sub-pixels 121, n1 and n2 are integers greater than 0, and n1≤n2.

When n1 is less than n2, that is, the number of second sub-pixels 121 with a relatively small light output view angle is large. In this way, when the second mode (i.e., anti-peeping mode) is started, although no first sub-pixels 111 but second sub-pixels 121 emit light, it is still possible to ensure that a relatively large number of second sub-pixels emit light, thereby ensuring the display effect in anti-peeping mode (anti-peeping mode can be understood as non-large visual mode or positive viewing angle mode).

It should be noted that in FIGS. 2 to 9, each patterning in the pixel units may be understood as a shape of orthographic projection of the light-emitting structure of the sub-pixel on the plane where the display panel is located. The shape of the orthographic projection of the light-emitting structure of the sub-pixel on the plane where the display panel is located is, for example, roughly rectangular, triangular, or other shapes. The rectangle or triangle may have chamfers, such as arc chamfers.

Exemplarily, the sub-pixel includes an anode, a light-emitting layer, and a cathode that are stacked, and the light-emitting layer is located between the anode and the cathode. In the present application, the “light-emitting structure” herein refers to the light-emitting layer.

Exemplarily, in the same one of the pixel units 10, an area ratio of orthographic projections on a plane where the display panel is located among light-emitting structures with different light-emission colors of the first sub-pixels is equal to an area ratio of orthographic projections on a plane where the display panel is located among light-emitting structures with different light-emission colors of the second sub-pixels. Taking FIG. 2 as an example, in the same sub-pixel group, the first sub-pixels with different light-emission colors are labeled as R1, G1, and B1 respectively, and the second sub-pixels with different light-emission colors are labeled as R2, R2′, G2, G2′, B2, and B2′ respectively, wherein S(R1):S(G1):S(B1)=S(R2+R2′):S(G2+G2′):S(B2+B2′). Here, S(R1) represents an orthographic projection area of the light-emitting structure of the sub-pixel R1 on the plane where the display panel is located, and S(R2+R2′) represents a sum of the orthographic projection areas of the light-emitting structures of the sub-pixel R2 and sub-pixel R2′ on the plane where the display panel is located. The interpretation also holds true for the other expressions, which are not explained one by one here. In the embodiments, the light emissions of the first sub-pixel and second sub-pixel are relatively uniform in the first mode.

In some embodiments, in the same sub-pixel group 13, a total area of orthographic projections, on the plane where the display panel is located, of the light-emitting structures of n1 first sub-pixels 111 is S1, and a total area of orthographic projections, on the plane where the display panel is located, of the light-emitting structures of n2 second sub-pixels 121 is S2, and the difference between S1 and S2 is within 10%.

For example, S1 and S2 are equal, or the difference between S1 and S2 is 10%, or the difference between S1 and S2 is smaller than 10%.

The difference between S1 and S2 is within 10%, that is, the area occupied by the light-emitting structures of n2 second sub-pixels 121 in the same sub-pixel group 13 is not too small, so when the second mode (i.e., the anti-peeping mode) is started, although first sub-pixels 111 do not emit light, only second sub-pixels 121 emit light, the display effect in the anti-peeping mode (the anti-peeping mode may be understood as a non-large visual mode or a positive viewing angle mode) can also be guaranteed.

First, some examples of n2>n1 are described below.

In some embodiments, as shown in FIG. 2, FIG. 4, and FIG. 8, in the same sub-pixel group 13, at least one second sub-pixel 121 is disposed on each one of two sides of the first sub-pixel 111. In the same sub-pixel group 13, at least two second sub-pixels 121 are spaced apart by the first sub-pixel 111, so that different types of sub-pixels of the display panel are distributed relatively evenly as a whole, which is conducive to ensuring the display effect in different modes.

In some embodiments, as shown in FIG. 2, FIG. 4, and FIG. 8, in the same sub-pixel group 13, at least one second sub-pixel 121 is disposed on each one of two sides of the first sub-pixel 111, and further, in the same sub-pixel group 13, n1=1, n2=2.

In a case where the area occupied by the sub-pixel group is certain, the larger the number of n1 and n2, the more sub-pixels need to be placed in a certain area, and the smaller the area occupied by a single sub-pixel, which may pose a greater challenge to the preparation process.

In the embodiments of the present application, the total number of sub-pixels in the same sub-pixel group 13 is 3, and two second sub-pixels are located on both sides of the first sub-pixel respectively, which can ensure that the sub-pixels of different types on the display panel are distributed relatively evenly as a whole, and can also avoid a greater challenge on the preparation process.

In the present application, multiple sub-pixels of a sub-pixel group can be regarded as being obtained by splitting a large sub-pixel, and the split part is used as the first sub-pixel and the other part is used as the second sub-pixel.

It should be noted that, in the process of preparing the display panel, when forming multiple sub-pixels of the same sub-pixel, it is not necessary to actually perform the step of “splitting”. The word “splitting” is used here to describe the multiple sub-pixels in a sub-pixel group more vividly.

In some embodiments, as shown in FIGS. 2, 4, and 8, in the same sub-pixel group 13, the light-emitting structures of the two second sub-pixels 121 are centrally symmetrical.

Exemplarily, in the same sub-pixel group 13, the light-emitting structures of the two second sub-pixels 121 have the same shape of orthographic projection on the plane where the display panel is located, and, in the same sub-pixel group 13, the light-emitting structures of the two second sub-pixels 121 have the same area of orthographic projection on the plane where the display panel is located.

For example, in two second sub-pixels 121, the light-emitting structure of one second sub-pixel 121 is rotated by 180°, and then moved to a position where the light-emitting structure of the other second sub-pixel 121 is located, the two light-emitting structures may overlap.

It should be noted that the light-emitting structures of the two second sub-pixels 121 being centrally symmetrical include: the light-emitting structures of the two second sub-pixels 121 being approximately centrally symmetrical, allowing a certain error.

In the embodiments of the present application, in the same sub-pixel group 13, the light-emitting structures of the two second sub-pixels 121 are centrally symmetrical, so that visually, the light emissions of the second sub-pixels 121 are relatively uniform, which is conducive to improving the display visual effect.

The above examples introduce some examples of n2>n1, and some examples of n1=n2 are described below.

In some embodiments, in the same sub-pixel group, n1=1, n2=1.

In a case that the area occupied by the sub-pixel group is certain, the larger the number of n1 and n2, the more sub-pixels need to be placed in a certain area, and the smaller the area occupied by a single sub-pixel, which may pose a greater challenge to the preparation process.

In the embodiments of the present application, the total number of sub-pixels in the same sub-pixel group 13 is 2, which can not only ensure that different types of sub-pixels exist in the same sub-pixel group, but also better avoid the greater challenge to the preparation process.

In some embodiments, taking the structure shown in FIG. 6 as an example, in a case that n1=1 and n2=1, in the same sub-pixel group 13, the light-emitting structure of first sub-pixel 111 and the light-emitting structure of second sub-pixel 121 are centrally symmetrical.

Exemplarily, in the same sub-pixel group 13, the light-emitting structure of first sub-pixel 111 and the light-emitting structure of second sub-pixel 121 have the same shape of orthographic projection on the plane where the display panel is located, and, in the same sub-pixel group 13, the light-emitting structure of first sub-pixel 111 and the light-emitting structure of second sub-pixel 121 have the same area of orthographic projection on the plane where the display panel is located.

For example, in the light-emitting structure of first sub-pixel 111 and the light-emitting structure of second sub-pixel 121, the light-emitting structure of first sub-pixel 111 is rotated by 180° and then moves to a position where the light-emitting structure of second sub-pixel 121 is located, the two light-emitting structures may overlap.

It should be noted that the light-emitting structure of first sub-pixel 111 and the light-emitting structure of second sub-pixel 121 being centrally symmetrical include: the light-emitting structure of first sub-pixel 111 and the light-emitting structure of second sub-pixel 121 being approximately centrally symmetrical, allowing a certain error.

In the embodiments of the present application, in the same sub-pixel group 13, the light-emitting structure of first sub-pixel 111 and the light-emitting structure of second sub-pixel 121 are centrally symmetrical, so that visually, the light emissions of first sub-pixel 111 and second sub-pixel 121 are relatively uniform, which is conducive to improving the display visual effect.

In some embodiments, as shown in FIG. 6, in a case that n1=1 and n2=1, the orthographic projections of the light-emitting structure of first sub-pixel 111 and the light-emitting structure of second sub-pixel 121 in sub-pixel group 13 on the plane where the display panel is located are both triangles.

It should be noted that the orthographic projections of the light-emitting structures of sub-pixels on the plane where the display panel is located are both triangles, which includes: the orthographic projections of the light-emitting structures of sub-pixels on the plane where the display panel is located are approximately triangles, then the shapes of orthographic projections of the light-emitting structures of sub-pixels on the plane where the display panel is located may be considered as triangles. The triangle is not a triangle in a strict sense, and the triangle may have rounded angles, and the sides of the triangle may be straight sides, arc sides, or even sawtooth or wavy sides.

In order to more vividly illustrate the shapes of the light-emitting structures, for example, the light-emitting structure of first sub-pixel 111 and the light-emitting structure of second sub-pixel 121 can be regarded as being obtained by splitting a roughly rectangular or square light-emitting structure into two parts, one part of which is used as the light-emitting structure of first sub-pixel 111, and the other part is used as the light-emitting structure of second sub-pixel 121. It can be divided into two equal parts or unequal parts. The dividing line may be a straight line, an arc line, or a line of other shapes. The shapes of other sub-pixels in the same sub-pixel group as shown in FIGS. 2, 4, and 8 may also be understood similarly.

However, it should be noted that when preparing the first sub-pixel and the second sub-pixel, the first sub-pixel and the second sub-pixel are not prepared by splitting in this way.

In the embodiments of the present application, the orthographic projections of the light-emitting structure of the first sub-pixel 111 and the light-emitting structure of the second sub-pixel 121 on the plane where the display panel is located are both triangles, so that the orthographic projections of the multiple light-emitting structures in the sub-pixel group 13 on the plane where the display panel is located can form a rectangle or a square as a whole. In a case that the area of the display panel is constant, more sub-pixel groups can be arranged in this way, which is conducive to improving the resolution of the display panel.

In some embodiments, in the same sub-pixel group 13, regardless of the number of n1 and n2, the orthographic projections of the multiple light-emitting structures in the sub-pixel group 13 on the plane where the display panel is located can form a rectangle or a square as a whole. For example, taking FIG. 8 as an example, it can be understood that a large light-emitting structure is split into three parts, two of which are used as the light-emitting structure of the second sub-pixel 121, and one of which is used as the light-emitting structure of the first sub-pixel 111.

In some embodiments, as shown in FIG. 6 or FIG. 8, extending directions of the partition walls 20 of at least two sub-pixel groups of light-emission colors are different. For example, an extending direction of the partition wall 20 of the first sub-pixel group 131 is Z1, an extending direction of the partition wall 20 of the second sub-pixel group 132 is Z2, and the extending direction of the partition wall 20 of the third sub-pixel group 133 is Z3, and the directions Z1, Z2, and Z3 are different from each other. Different sub-pixel groups occupy different areas, or in other words, the overall shapes of different sub-pixel groups are different in size, so the extending directions of the partition walls of different sub-pixel groups are different, which can better ensure that the spacing distances in different display modes between the light-emitting sub-pixels do not change.

Next, some design methods that can achieve different light output viewing angles of different sub-pixels are introduced. It should be noted that the design methods that can achieve different light output viewing angles of different sub-pixels introduced in the embodiments of the present application are only some examples and are not used to limit the present application. The technical solutions of the present application for the unchanged spacing distances in the two modes between the light-emitting sub-pixels are universal, that is, the technical solutions of the present application for the unchanged spacing distances in the two modes between the light-emitting sub-pixels can also be applied to other design methods that can achieve different light output viewing angles of different sub-pixels.

In some embodiments, taking FIG. 2 and FIG. 10 as an example, the first pixel 11 includes the first sub-pixels 111, the second pixel 12 includes the second sub-pixels 121, and the display panel further includes a first light-guiding structure 31 and/or a second light-guiding structure 32, the first light-guiding structure 31 is located at a light-emitting side of the first sub-pixels 111, and the second light-guiding structure 32 is located at a light-emitting side of the second sub-pixels 121. The first light-guiding structure 31 and/or the second light-guiding structure 32 can adjust the light output viewing angles of the sub-pixels. Specifically, the thick solid line with an arrow in FIG. 10 represents the light ray. The first light-guiding structure 31 can diffuse and then output the light rays emitted by the first sub-pixels 111, and the second light-guiding structure 32 can converge and then output the light rays emitted by the second sub-pixels 121, so that the light output viewing angle of the first sub-pixels 111 is greater than the light output viewing angle of the second sub-pixels 121.

Exemplarily, the display panel includes a substrate 101, and the light-emitting structure of the sub-pixel is located on one side of the substrate 101. For example, the display panel includes an anode layer 102, a light-emitting layer 103 and a cathode layer 104, and the light-emitting structure of the sub-pixel includes an anode, a light-emitting material and a cathode.

The anode of the light-emitting structure is located in the anode layer 102, the light-emitting material of the light-emitting structure is located in the light-emitting layer 103, and the cathode of the light-emitting structure is located in the cathode layer. One anode corresponds to one light-emitting structure, and different anodes are separated by pixel definition layers PDLs.

The display panel may also include an encapsulation layer 105, and the encapsulation layer 105 is located on one side of the cathode layer 104 facing away from the substrate 101. The first light-guiding structure 31 and the second light-guiding structure 32 are located on one side of the encapsulation layer 105 facing away from the substrate 101, and the orthographic projections of the first light-guiding structure 31 and the anode of the first sub-pixel 111 on the substrate 101 overlap, and the orthographic projections of the second light-guiding structure 32 and the anode of the second sub-pixel 121 on the substrate 101 overlap.

As shown in FIG. 10, the display panel may also include a cover plate 106 and a polarizer 107. For example, the cover plate 106 may be a glass cover plate or a cover plate made of other materials.

In the embodiments of the present application, a first light-guiding structure capable of diffusing light rays is provided corresponding to first sub-pixels, and a second light-guiding structure capable of converging light rays is provided corresponding to second sub-pixels, so that the light output viewing angle of first sub-pixels is greater than that of second sub-pixels.

In some embodiments, still referring to FIG. 10, the first light-guiding structure 31 includes a first lens layer 311 and a first filling layer 312 which are stacked and have different refractive indices, and the contact surface of the first lens layer 311 with the first filling layer 312 is a first arc surface f1. The second light-guiding structure 32 includes a second lens layer 321 and a second filling layer 322 which are stacked and have different refractive indices, and the contact surface of the second lens layer 321 with the second filling layer 322 is a second arc surface f2.

It can be understood that the surface of the first lens layer 311 facing the first filling layer 312 is an arc surface, the surface of the first filling layer 312 facing the first lens layer 311 is an arc surface, and the opposite surfaces of the first lens layer 311 and the first filling layer 312 match each other. The surface of the second lens layer 321 facing the second filling layer 322 is an arc surface, the surface of the second filling layer 322 facing the second lens layer 321 is an arc surface, and the opposite surfaces of the second lens layer 321 and the second filling layer 322 match each other.

The curvature of the first arc surface f1 and the second arc surface f2 may be the same or different, which is not limited in the present application.

Exemplarily, the upper and lower surfaces of the first light-guiding structure 31 are both planes, and the upper and lower surfaces of the second light-guiding structure 32 are both planes. That is to say, the surface of the first lens layer 311 facing away from the first filling layer 312 is a plane, and the surface of the first filling layer 312 facing away from the first lens layer 311 is a plane. The surface of the second lens layer 321 facing away from the second filling layer 322 is a plane, and the surface of the second filling layer 322 facing away from the second lens layer 321 is a plane.

In the embodiments of the present application, the light-guiding structure includes a lens layer and a filling layer that are stacked and have different refractive indices, and the contact surface of the lens layer with the filling layer is an arc surface, so that the propagation direction of the light ray at the contact surface may change, thereby facilitating the realization of a light-guiding structure with a light-convergence effect or a light-diffusion effect.

The following first introduces some specific structures of the first light-guiding structure.

In some embodiments, as shown in FIG. 10, the first arc surface f1 is an arc surface convex toward the first sub-pixel 111, the first filling layer 312 is located between the first sub-pixels 111 and the first lens layer 311, and the refractive index of the first filling layer 312 is greater than the refractive index of the first lens layer 311.

Since the first filling layer 312 is closer to the first sub-pixel 111, and the refractive index of the first filling layer 312 is greater than the refractive index of the first lens layer 311, the light rays emitted from the first sub-pixel 111 reaches the first arc surface f1 through the first filling layer 312, and is refracted at the first arc surface f1, and is emitted outward at a larger angle, thereby achieving diffusion of the light rays, so that the light output viewing angle of the first sub-pixels 111 is relatively larger.

In other embodiments, as shown in FIG. 11, the first arc surface f1 is an arc surface convex away from the first sub-pixel 111, the first lens layer 311 is located between the first sub-pixel 111 and the first filling layer 312, and the refractive index of the first filling layer 312 is less than the refractive index of the first lens layer 311.

Since the first lens layer 311 is closer to the first sub-pixel 111, and the refractive index of the first lens layer 311 is greater than the refractive index of the first filling layer 312, the light emitted from the first sub-pixel 111 reaches the first arc surface f1 through the first lens layer 311, and is refracted on the first arc surface f1, and is emitted outward at a larger angle, thereby achieving the diffusion of the light, so that the light output viewing angle of the first sub-pixels 111 is relatively larger.

The following is an introduction to some specific structures of the second light-guiding structure.

In some embodiments, as shown in FIG. 10 or FIG. 11, the second arc surface f2 is an arc surface convex away from the second sub-pixel 121, and the second lens layer 321 is located between the second sub-pixel 121 and the second filling layer 322, and the refractive index of the second filling layer 322 is greater than the refractive index of the second lens layer 321.

Since the second lens layer 321 is closer to the second sub-pixel 121, and the refractive index of the second lens layer 321 is less than the refractive index of the second filling layer 322, the light rays emitted from the second sub-pixel 121 reaches the second arc surface f2 through the second lens layer 321, is refracted at the second arc surface f2, and is emitted outward at a smaller angle, thereby achieving the convergence of the light rays, so that the light output viewing angle of the second sub-pixels 121 is relatively small.

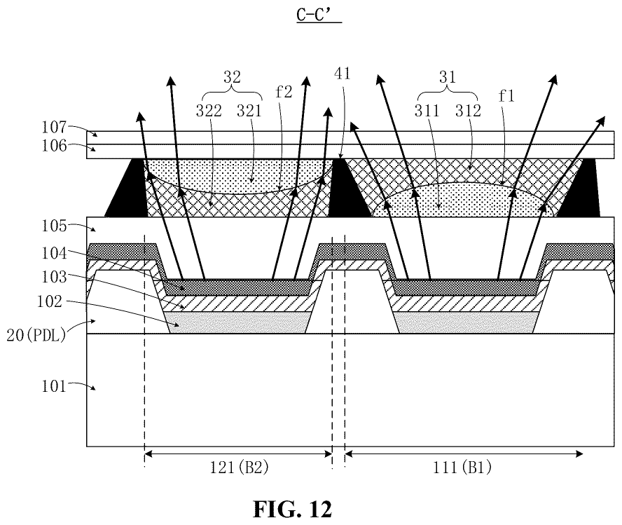

In other embodiments, as shown in FIG. 12, the second arc surface f2 is an arc surface convex toward the second sub-pixel 121, and the second filling layer 322 is located between the second sub-pixel 121 and the second lens layer 321, and the refractive index of the second filling layer 322 is less than the refractive index of the second lens layer 321.

Since the second filling layer 322 is closer to the second sub-pixel 121, and the refractive index of the second filling layer 322 is less than the refractive index of the second filling layer 322, the light rays emitted from the second sub-pixel 121 reaches the second arc surface f2 through the second filling layer 322, is refracted on the second arc surface f2, and is emitted outward at a smaller angle, thereby realizing the convergence of the light rays, so that the light output viewing angle of the second sub-pixels 121 is relatively small.

The above introduces two design methods of the first light-guiding structure and two design methods of the second light-guiding structure, and any design method of the first light-guiding structure and any design method of the second light-guiding structure can be selected.

As an example, as shown in FIG. 10, the design method of the first light-guiding structure 31 is that: the first arc surface f1 is an arc surface convex toward the first sub-pixel 111, the first filling layer 312 is located between the first sub-pixel 111 and the first lens layer 311, and the refractive index of the first filling layer 312 is greater than the refractive index of the first lens layer 311. Moreover, the design method of the second light-guiding structure 32 is that: the second arc surface f2 is an arc surface convex away from the second sub-pixel 121, the second lens layer 321 is located between the second sub-pixel 121 and the second filling layer 322, and the refractive index of the second filling layer 322 is greater than that of the second lens layer 321.

Exemplarily, in FIG. 10, the refractive index of the first lens layer 311 is equal to the refractive index of the second lens layer 321, and the refractive index of the second filling layer 322 is equal to the refractive index of the first filling layer 312.

As an example, as shown in FIG. 11, the design method of the first light-guiding structure 31 is that: the first arc surface f1 is an arc surface convex away from the first sub-pixel 111, the first lens layer 311 is located between the first sub-pixel 111 and the first filling layer 312, and the refractive index of the first filling layer 312 is less than the refractive index of the first lens layer 311. Moreover, the design method of second light-guiding structure 32 is that: the second arc surface f2 is an arc surface convex away from the second sub-pixel 121, the second lens layer 321 is located between the second sub-pixel 121 and the second filling layer 322, and the refractive index of the second filling layer 322 is greater than the refractive index of the second lens layer 321.

Exemplarily, in FIG. 11, the refractive index of the first lens layer 311 is equal to the refractive index of the second lens layer 321, and the refractive index of the second filling layer 322 is greater than the refractive index of the first filling layer 312.

In other examples, it can also be designed that only the first sub-pixel is provided with a first light-guiding structure with a light-diffusion function, while the second sub-pixel is not provided with a second light-guiding structure with a light-convergence function; or, it can be designed that only the second sub-pixel is provided with a second light-guiding structure with a light-convergence function, while the first sub-pixel is not provided with a first light-guiding structure with a light-diffusion function.

In some examples, as shown in FIG. 10, the first light-guiding structure 31 and the second light-guiding structure 32 are spaced apart by a first light-shielding structure 41. Exemplarily, the material of the first light-shielding structure 41 includes a black matrix (BM). It is understood that the light-shielding structure can prevent light rays from passing through.

The first light-shielding structure 41 includes a first side surface c1 and a second side surface c2, the first side surface c1 faces towards the first light-guiding structure 31, the second side surface c2 faces towards the second light-guiding structure 32, the angle θ1 between the first side surface c1 and the plane where the display panel is located is an obtuse angle, and the angle θ2 between the second side surface c2 and the plane where the display panel is located is less than or equal to 90°.

For example, the angle θ1 is 135° or other values greater than 90° and less than 180°. The angle θ2 is 90° or other values less than 90° and greater than 0°. The larger the angle θ1 is, the greater the light output viewing angle of the first sub-pixels 111 can be, and the smaller the angle θ2 is, the smaller the light output viewing angle of the second sub-pixels 121 can be.

Exemplarily, both the first side surface c1 and the second side surface c2 are inclined planes, and in a direction toward the light output surface close to the display panel, the area of the opening enclosed by the first side surface c1 becomes larger and larger, and the area of the opening enclosed by the second side surface c2 becomes smaller and smaller.

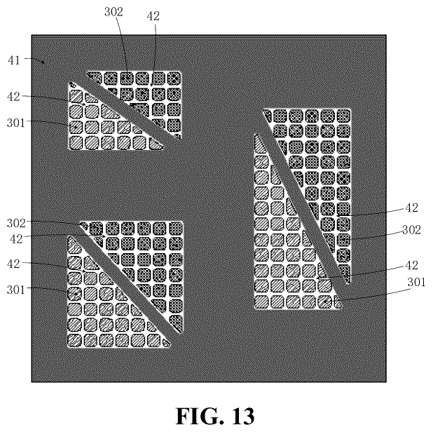

In some embodiments, as shown in FIG. 13, the first light-guiding structure 31 includes a plurality of first light-guiding units 301 arranged at intervals, and different first light-guiding units 301 are spaced apart from one another by a second light-shielding structure 42; and/or, the second light-guiding structure 32 includes a plurality of second light-guiding units 302 arranged at intervals, and different second light-guiding units 302 are spaced apart from one another by a second light-shielding structure 42.

Exemplarily, the second light-shielding structure 42 may also include BM.

Exemplarily, the structure of each first light-guiding unit 301 is the same as the specific structure of the first light-guiding structure 31 described in the above examples. The structure of each second light-guiding unit 302 is the same as the specific structure of the second light-guiding structure 32 described in the above examples.

Multiple first light-guiding units 301 corresponding to the same first sub-pixel may be distributed in an array. Multiple second light-guiding units 302 corresponding to the same second sub-pixel may be distributed in an array.

The light-guiding structures corresponding to multiple sub-pixels of the same sub-pixel group 13 are spaced apart by the first light-shielding structures 41, and the light-guiding structures of different sub-pixel groups 13 may also be spaced apart by the first light-shielding structures 41. The first light-shielding structures 41 and the second light-shielding structures 42 are interconnected to be in a grid form as a whole.

In the embodiments of the present application, the first light-guiding structure is divided into multiple small first light-guiding units, which can better diffuse the light rays; the second light-guiding structure is divided into multiple small second light-guiding units, which can better converge the light rays.

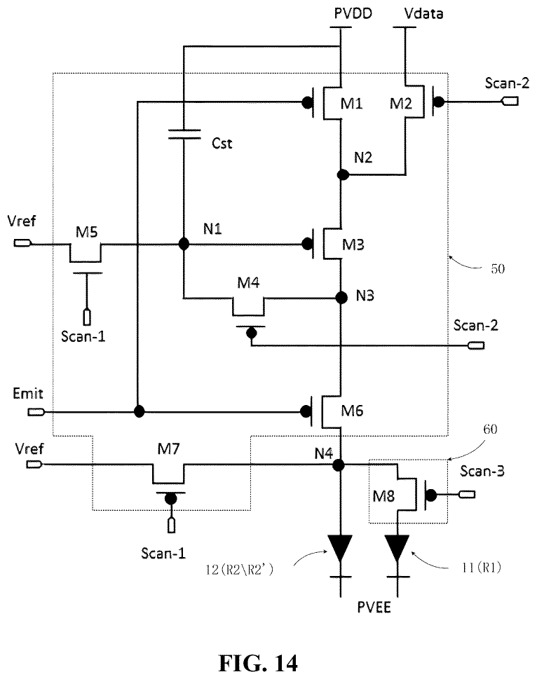

In some embodiments, as shown in FIG. 14, the display panel further includes a pixel driving circuit 50, a first end of the pixel driving circuit 50 is electrically connected to the first power supply end PVDD, a second end of the pixel driving circuit 50 is electrically connected to the first pixel 11 and the second pixel 12, one of the first pixel 11 and the second pixel 12 is directly electrically connected to the output end of the pixel driving circuit 50, and the other is electrically connected to the output end of the pixel driving circuit 50 through the gating module 60.

In FIG. 14, the second pixel 12 is directly electrically connected to the output end of the pixel driving circuit 50, and the first pixel 11 is electrically connected to the output end of the pixel driving circuit 50 through the gating module 60. It can be understood that it can also be designed as follows: the first pixel 11 is directly electrically connected to the output end of the pixel driving circuit 50, and the second pixel 12 is electrically connected to the output end of the pixel driving circuit 50 through the gating module 60.

In the embodiments of the present application, the first pixel and the second pixel share a pixel driving circuit, which can reduce the number of pixel driving circuits and improve the resolution of the display panel.

Exemplarily, the first pixel includes first sub-pixels of multiple light-emission colors, and the second pixel includes second sub-pixels of multiple light-emission colors. Specifically, in the same sub-pixel group, the first sub-pixel and the second sub-pixel of the same light-emission color share a pixel driving circuit, and sub-pixels of different light-emission colors are connected to different pixel driving circuits. For example, in the same sub-pixel group, red sub-pixels R1, R2, and R2′ share a pixel driving circuit, green sub-pixels G1, G2, and G2′ share another pixel driving circuit, and blue sub-pixels B1, B2, and B2′ share another pixel driving circuit. That is, corresponding to one pixel unit, there are three sub-pixel groups with different light-emission colors, and three pixel driving circuits are designed. For n pixel units, 3*n pixel driving circuits may be designed.

Exemplarily, FIG. 14 takes as an example that the pixel driving circuit 50 includes 7 transistors and 1 storage capacitor, which is not intended to limit the present application. In other examples, the pixel driving circuit 50 may be a circuit of other structures.

In some examples, in the first mode, the gating module 60 is turned on, and the driving current generated by the pixel driving circuit 50 drives both first pixel and second pixel to emit light. In the second mode, the gating module 60 is turned off. The driving current generated by the pixel driving circuit 50 is only transmitted to the pixels directly electrically connected to the pixel driving circuit 50. For example, in the second mode, only second pixel needs to emit light, so the pixel driving circuit 50 is directly electrically connected to second pixel, so that the pixel driving circuit 50 only drives second pixel to emit light.

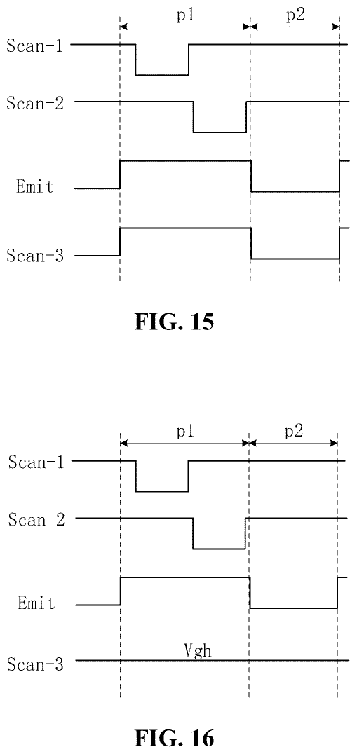

Exemplarily, as shown in FIG. 15 and FIG. 16, FIG. 15 specifically shows a timing sequence diagram of the pixel driving circuit in the first mode, and FIG. 16 specifically shows a timing sequence diagram of the pixel driving circuit in the second mode. The working process of the pixel circuit may include a pre-stage p1 and a light-emitting stage p2. In the pre-stage p1, the scan signals Scan-1 and Scan-2 are respectively at active levels. When the scan signal Scan-1 is at an active level, the reset signal Vref resets the gate of the driving transistor M3 and the anode of the light-emitting structure. When the scan signal Scan-2 is at an active level, the data signal Vdata is written, and the transistor M4 compensates the threshold voltage of the driving transistor M3. In the light-emitting stage p2, the light-emitting control signal Emit is at a low level, and the pixel driving circuit generates a driving current to drive the corresponding pixel to emit light.

It should be noted that the valid level is illustrated as a low level in FIGS. 15 and 16.

As shown in FIG. 15, in the first mode, the scan signal Scan-3 is at a high level in the pre-stage p1, and the gating module 60 is disconnected; the scan signal Scan-3 is at a low level in the light-emitting stage p2, and the gating module 60 is turned on.

As shown in FIG. 16, in the second mode, the scan signal Scan-3 is at a high level (Vgh) in the pre-stage p1 and the light-emitting stage p2, and the gating module 60 remains disconnected.

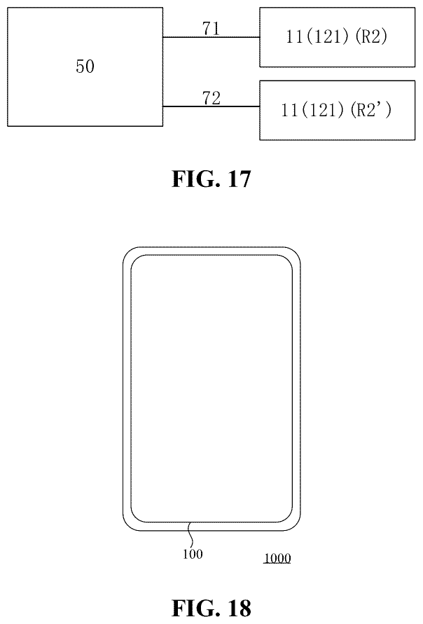

In some embodiments, as shown in FIG. 17, the pixel driving circuit 50 is electrically connected to multiple second pixels 12 through multiple connecting lines. The multiple second pixels 12 here refer to multiple second sub-pixels 121 of the same light-emission color.

For example, the second sub-pixel 121 includes sub-pixels R2 and R2′, sub-pixel R2 is electrically connected to the pixel driving circuit 50 through the first connecting line 71, and sub-pixel R2′ is electrically connected to the pixel driving circuit 50 through the second connecting line 72. The anodes of sub-pixels R2 and R2′ are spaced apart from each other.

It should be noted that the transistor in the embodiments of the present application may be an N-type transistor or a P-type transistor. For an N-type transistor, the on-level is a high level and the off-level is a low level. That is, when the gate potential of the N-type transistor is at a high level, the first electrode and the second electrode of the N-type transistor are connected, and when the gate potential of the N-type transistor is at a low level, the first electrode and the second electrode of the N-type transistor are disconnected. For a P-type transistor, the on-level is a low level and the off-level is a high level. That is, when the gate potential of the P-type transistor is a low level, the first electrode and the second electrode of the P-type transistor are connected, and when the gate potential of the P-type transistor is at a high level, the first electrode and the second electrode of the P-type transistor are disconnected. In a specific implementation, the gate of each of the above-mentioned transistors serves as its control electrode, and, according to the signal of the gate and its type of each transistor, its first electrode can be used as the source and the second electrode as the drain, or its first electrode can be used as the drain and the second electrode as the source, without making any distinction here. In addition, the on-level and off-level in the embodiments of the present application are general terms, the on-level refers to any level that can turn on the transistor, and the off-level refers to any level that can turn off/shut down the transistor.

It should be noted that in the embodiments shown in the above figures, the resistor is expressed as a single resistor, and the capacitor is expressed as a single capacitor. In other embodiments, the resistor can also be an integration of series, parallel or mixed resistors, and the capacitor can also be an integration of series, parallel or mixed capacitors. The specific parameters of each device can be set according to actual needs, which are not limited in the present application.

The electrical connection described in the present application can be a direct connection, that is, a connection between two components, or an indirect connection, that is, an indirect connection can be formed between two components through one or more elements.

The present application also provides a display apparatus, including a display panel provided by the present application. Referring to FIG. 18, FIG. 18 is a schematic structural diagram of a display apparatus provided in an embodiment of the present application. The display apparatus 1000 provided in FIG. 18 includes a display panel 100, and the display panel 100 includes a display panel provided in any one of the above embodiments of the present application. The embodiment of FIG. 18 only takes a mobile phone as an example to illustrate the display apparatus 1000. It can be understood that the display apparatus provided in the embodiments of the present application may be a wearable product, a computer, a television, a car display apparatus, and other display apparatuses with display functions, which is not specifically limited in the present application. The display apparatus provided in the embodiments of the present application has the beneficial effects of the display panel provided in the embodiments of the present application. For details, the specific description of the display panel in the above embodiments is referred to and is not be repeated in detail in the present embodiments.

According to the embodiments of the present application as described above, these embodiments do not describe all the details in detail, nor do they limit the present application to the specific embodiments described. Apparently, according to the above description, many modifications and changes can be made. The present specification selects and describes these embodiments in detail in order to better explain the principles and practical applications of the present application, so that technicians in the relevant technical field can make good use of the present application and modifications based on the present application. The present application is limited only by the claims and their full scope and equivalents.

What is claimed is:

1. A display panel, comprising a plurality of pixel units arranged in an array in a first direction and a second direction intersecting each other, the pixel unit comprising a first pixel and a second pixel, and a light output viewing angle of the first pixel being greater than a light output viewing angle of the second pixel,
wherein a display mode of the display panel comprises a first mode and a second mode;
in the first mode, the first pixel and the second pixel both emit light, a minimum spacing distance in the first direction between sub-pixels in a light-emitting state in the i-th pixel unit and the j-th pixel unit and having a same light-emission color is a1, and the i-th pixel unit and the j-th pixel unit are adjacent;
in the second mode, the first pixel does not emit light, the second pixel emits light, and a minimum spacing distance in the first direction between sub-pixels in a light-emitting state in the i-th pixel unit and the j-th pixel unit and having the same light-emission color is b1, and a1=b1; and
wherein at least one of the pixel units comprises a plurality of sub-pixel groups with different light-emission colors, and sub-pixels in the sub-pixel groups are spaced apart by partition walls, and the first direction intersects with an extending direction of the partition walls.

2. The display panel according to claim 1, wherein in the first mode, a minimum spacing distance in the first direction between sub-pixels in the light-emitting state in a same one of the pixel units and having a first light-emission color and a second light-emission color respectively is a2; and
in the second mode, a minimum spacing distance in the first direction between sub-pixels in the light-emitting state in the same one of the pixel units and having the first light-emission color and the second light-emission color respectively is b2; a2=b2.

3. The display panel according to claim 1, wherein each of the sub-pixel groups comprises n1 first sub-pixels and n2 second sub-pixels with a same light-emission color, a light output viewing angle of the first sub-pixels is greater than a light output viewing angle of the second sub-pixels, the first pixel comprises the first sub-pixels, the second pixel comprises the second sub-pixels, and n1 and n2 are integers greater than 0;
in a same one of the pixel units, the n1 first sub-pixels are arranged in a same rule for the sub-pixel groups each, the n2 second sub-pixels are arranged in a same rule for the sub-pixel groups each, and overall shapes of the sub-pixel groups are similar.

4. The display panel according to claim 1, wherein each of the sub-pixel groups comprises n1 first sub-pixels and n2 second sub-pixels with a same light-emission color, a light output viewing angle of the first sub-pixels is greater than a light output viewing angle of the second sub-pixels, the first pixel comprises the first sub-pixels, the second pixel comprises the second sub-pixels, n1≤n2, and n1 and n2 are integers greater than 0.

5. The display panel according to claim 4, wherein under a condition that n1=1 and n2=2 in a same one of the sub-pixel groups, light-emitting structures of the two second sub-pixels are centrally symmetrical; or under a condition that n1=1 and n2=1 in a same one of the sub-pixel groups, the light-emitting structure of the first sub-pixel and the light-emitting structure of the second sub-pixel are centrally symmetrical.

6. The display panel according to claim 5, wherein under the condition that n1=1 and n2=1 in the same one of the sub-pixel groups, the partition walls of the sub-pixel groups with at least two respective light-emission colors have different extending directions.

7. The display panel according to claim 4, wherein in a same one of the sub-pixel groups, a total area of orthographic projections, on a plane where the display panel is located, of anodes of the n1 first sub-pixels is S1, and a total area of orthographic projections, on a plane where the display panel is located, of anodes of the n2 second sub-pixels is S2, and a difference between S1 and S2 is within 10%.

8. The display panel according to claim 1, wherein the first pixel comprises first sub-pixels, the second pixel comprises second sub-pixels, and the display panel further comprises a first light-guiding structure and/or a second light-guiding structure, the first light-guiding structure is located at a light-emitting side of the first sub-pixels, the second light-guiding structure is located at a light-emitting side of the second sub-pixels, the first light-guiding structure is capable of diffusing and then outputting light rays emitted by the first sub-pixels, and the second light-guiding structure is capable of converging and then outputting light rays emitted by the second sub-pixels.

9. The display panel according to claim 8, wherein the first light-guiding structure comprises a first lens layer and a first filling layer that are stacked and have different refractive indices, and a contact surface of the first lens layer with the first filling layer is a first arc surface; and
the second light-guiding structure comprises a second lens layer and a second filling layer that are stacked and have different refractive indices, and a contact surface of the second lens layer with the second filling layer is a second arc surface.

10. The display panel according to claim 9, wherein the first arc surface is an arc surface convex toward the first sub-pixel, the first filling layer is located between the first sub-pixel and the first lens layer, and the refractive index of the first filling layer is greater than the refractive index of the first lens layer; or the first arc surface is an arc surface convex away from the first sub-pixel, the first lens layer is located between the first sub-pixel and the first filling layer, and the refractive index of the first filling layer is less than the refractive index of the first lens layer.

11. The display panel according to claim 10, wherein the second arc surface is an arc surface convex away from the second sub-pixel, the second lens layer is located between the second sub-pixel and the second filling layer, and the refractive index of the second filling layer is greater than the refractive index of the second lens layer; or the second arc surface is an arc surface convex toward the second sub-pixel, the second filling layer is located between the second sub-pixel and the second lens layer, and the refractive index of the second filling layer is less than the refractive index of the second lens layer.

12. The display panel according to claim 8, wherein the first light-guiding structure and the second light-guiding structure are spaced apart by a first light-shielding structure;
the first light-shielding structure comprises a first side surface and a second side surface, the first side surface faces the first light-guiding structure, the second side surface faces the second light-guiding structure, an angle between the first side surface and a plane where the display panel is located is an obtuse angle, and an angle between the second side surface and the plane where the display panel is located is less than or equal to 90°.

13. The display panel according to claim 8, wherein the first light-guiding structure comprises a plurality of first light-guiding units arranged at intervals, and the first light-guiding units are spaced apart from one another by a second light-shielding structure; and/or
the second light-guiding structure comprises a plurality of second light-guiding units arranged at intervals, and the second light-guiding units are spaced apart from one another by a second light-shielding structure.

14. The display panel according to claim 1, wherein the display panel further comprises a pixel driving circuit, a first end of the pixel driving circuit is electrically connected to a first power supply end, a second end of the pixel driving circuit is electrically connected to the first pixel and the second pixel, one of the first pixel and the second pixel is directly electrically connected to an output end of the pixel driving circuit, and the other is electrically connected to the output end of the pixel driving circuit through a gating module.

15. The display panel according to claim 14, wherein in the first mode, the gating module is turned on; and
in the second mode, the gating module is turned off.

16. The display panel according to claim 14, wherein the pixel driving circuit is electrically connected to a plurality of the second pixels through a plurality of connecting lines.

17. The display panel according to claim 1, wherein in a same one of the pixel units, an area ratio of orthographic projections on a plane where the display panel is located among light-emitting structures with different light-emission colors of the first sub-pixels is equal to an area ratio of orthographic projections on the plane where the display panel is located among light-emitting structures with different light-emission colors of the second sub-pixels.

18. The display panel according to claim 9, wherein the first arc surface is an arc surface convex toward the first sub-pixel, the first filling layer is located between the first pixel and the first lens layer, and the refractive index of the first filling layer is greater than the refractive index of the first lens layer;
the second arc surface is an arc surface convex away from the second sub-pixel, the second lens layer is located between the second pixel and the second filling layer, and the refractive index of the second filling layer is greater than the refractive index of the second lens layer; and
the refractive index of the first lens layer is equal to the refractive index of the second lens layer, and the refractive index of the first filling layer is equal to the refractive index of the second filling layer.

19. The display panel according to claim 9, wherein the first arc surface is an arc surface convex away from the first sub-pixel, the first lens layer is located between the first pixel and the first filling layer, and the refractive index of the first filling layer is less than the refractive index of the first lens layer;
the second arc surface is an arc surface convex away from the second sub-pixel, the second lens layer is located between the second pixel and the second filling layer, and the refractive index of the second filling layer is greater than the refractive index of the second lens layer;
the refractive index of the first lens layer is equal to the refractive index of the second lens layer.

20. A display apparatus, comprising a display panel, wherein the display panel comprises: a plurality of pixel units arranged in an array in a first direction and a second direction intersecting each other, the pixel unit comprising a first pixel and a second pixel, and a light output viewing angle of the first pixel being greater than a light output viewing angle of the second pixel,
wherein a display mode of the display panel comprises a first mode and a second mode;
in the first mode, the first pixel and the second pixel both emit light, a minimum spacing distance in the first direction between sub-pixels in a light-emitting state in the i-th pixel unit and the j-th pixel unit and having a same light-emission color is a1, and the i-th pixel unit and the j-th pixel unit are adjacent;
in the second mode, the first pixel does not emit light, the second pixel emits light, and a minimum spacing distance in the first direction between sub-pixels in a light-emitting state in the i-th pixel unit and the j-th pixel unit and having the same light-emission color is b1, and a1=b1; and
wherein at least one of the pixel units comprises a plurality of sub-pixel groups with different light-emission colors, and sub-pixels in the sub-pixel groups are spaced apart by partition walls, and the first direction intersects with an extending direction of the partition walls.
